(19) United States
(12) Patent Application Publication
(10) Pub. No.: US 2026/0117381 A1
(43) Pub. Date: Apr. 30, 2026

(54) PEDESTAL SHROUD TO DIRECT FLOW OF PROCESS GASES AND BYPRODUCTS IN SUBSTRATE PROCESSING SYSTEMS

(71) Applicant: LAM RESEARCH CORPORATION, Fremont, CA (US)

(72) Inventors: Sachin Allamaprabhu KUBASAD, Dharwad (IN); Panya WONGSENAKHUM, Fremont, CA (US); Ravikumar PATIL, Bangalore (IN); Arun Kumar HOSUR SHIVALINGE GOWDA, Bangalore (IN); Sandeep GEHANI, Raipur (IN)

(21) Appl. No.: 18/841,499

(22) PCT Filed: Mar. 6, 2023
(86) PCT No.: PCT/US2023/014612

§ 371 Date: Aug. 26, 2024

(30) Foreign Application Priority Data
Mar. 8, 2022 (IN) 202211012613

(51) Int. Cl. C23C 16/458; C23C 16/44

(52) U.S. Cl. CPC C23C 16/4585; C23C 16/4404; C23C 16/4412

(57) ABSTRACT

A station of a substrate processing system includes a pedestal and a shroud. The pedestal is arranged in a well of the station. The pedestal includes a base portion to support a substrate and a stem portion extending from the base portion into the well of the station. The shroud is coupled to the base portion of the pedestal. The shroud surrounds the base portion and extends along the stem portion into the well of the station. The station further includes a liner lining an inner sidewall of the well of the station. The station further includes a liner lining a pedestal-facing surface of a bottom of the well of the station. The station further includes a hollow object disposed in the well of the station. The hollow object is of smaller dimensions than the well of the station.

### CROSS-REFERENCE TO RELATED APPLICATIONS

This application claims priority to Indian Patent Application No. 202211012613, filed on Mar. 8, 2022. The entire disclosure of the application referenced above is incorporated herein by reference.

### FIELD

The present disclosure relates generally to substrate processing systems and more particularly to a pedestal shroud to direct flow of process gases and byproducts in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). A typical ALD process comprises multiple dose and purge cycles that are repeated in quick succession in an alternating manner (e.g., dose, purge, dose, purge, and so on). Most ALD reactions use at least two chemicals called precursors (reactants) that react with the surface of the material one precursor at a time in a sequential, self-limiting manner. For example, a first reactant is supplied during a first dose cycle. The first dose cycle is followed by a purge cycle. Subsequently, a second reactant may be supplied during a second dose cycle. The second dose cycle is followed by a purge cycle, and so on. Through repeated exposure to separate precursors during dose cycles, a thin film is gradually deposited on the surface of the material.

Thermal ALD (T-ALD) is carried out in a heated processing chamber. The processing chamber is maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process.

### SUMMARY

A station of a substrate processing system comprises a pedestal and a shroud. The pedestal is arranged in a well of the station. The pedestal comprises a base portion to support a substrate and a stem portion extending from the base portion into the well of the station. The shroud is coupled to the base portion of the pedestal. The shroud surrounds the base portion and extends along the stem portion into the well of the station.

In an additional feature, the station further comprises a liner lining an inner sidewall of the well of the station.

In an additional feature, the station further comprises a liner lining a pedestal-facing surface of a bottom of the well of the station.

In an additional feature, the station further comprises a hollow object disposed in the well of the station. The hollow object is of smaller dimensions than the well of the station.

In additional features, the station further comprises a first liner, a second liner, and a hollow object. The first liner lines an inner sidewall of the well of the station. The second liner lines a pedestal-facing surface of a bottom of the well. The hollow object is disposed in the well. The well and the first liner are greater in height than the hollow object.

In additional features, the well comprises an exhaust port. The station further comprises a third liner lining the exhaust port wherein the first and second liners mate with the third liner.

In an additional feature, the second liner is annular with an outer edge contacting the first liner and an inner edge contacting the hollow object.

In an additional feature, a gap is maintained between the first liner and the shroud.

In additional features, the shroud, the first and second liners, the hollow object, the well, and the pedestal are concentric.

In additional features, the hollow object comprises an outer sidewall of a smaller diameter than the first liner and an inner sidewall of a diameter greater than the stem portion of the pedestal and wherein the first liner is taller than the hollow object.

In additional features, the second liner and the well comprise openings at respective centers. The stem portion of the pedestal passes through the inner sidewall of the hollow object and through the openings of the second liner and the well.

In additional features, the well comprises an exhaust port and an inlet for a gas. The gas flows around the hollow object and exits the well through the exhaust port.

In an additional feature, the station further comprises a third liner that lines the exhaust port and mates with the first and second liners.

In additional features, the station further comprises an edge ring disposed around the base portion of the pedestal. The shroud is mounted to the edge ring with a gap maintained between the shroud and the edge ring.

In additional features, the well comprises a first liner, a second liner, a hollow object, an exhaust port, and an inlet. The first liner lines an inner sidewall of the well. The second liner lines a pedestal-facing surface of a bottom of the well. The hollow object is disposed in the well. The well and the first liner are greater in height than the hollow object. Gases enter the well through the gap and the inlet, flow around the hollow object, and exit the well through the exhaust port.

In an additional feature, the station further comprises a third liner that lines the exhaust port and mates with the first and second liners.

In additional features, the well comprises an exhaust port. The station further comprises a first liner, a second liner, and a third liner. The first liner lines an inner sidewall of the well. The second liner lines a pedestal-facing surface of a bottom of the well. The third liner lines the exhaust port and mates with the first and the second liners.

In additional features, the station further comprises a hollow object disposed in the well. The hollow object is of smaller dimensions than the well. The first liner is greater in height than the hollow object. The second liner is annular with an outer edge contacting the first liner and an inner edge contacting the hollow object.

In additional features, the station further comprises an edge ring disposed around the base portion of the pedestal. The shroud is mounted to the edge ring with a gap maintained between the shroud and the edge ring. The well comprises an inlet. Gases enter the well through the gap and the inlet, flow around the hollow object, and exit the well through the exhaust port.

In additional features, the station further comprises an object comprising an outer sidewall, an inner sidewall, and a first surface connecting first ends of the outer sidewall and the inner sidewall. The object rests on a second surface of a bottom of the well, the second surface being opposite the first surface. A height of the object is less than a depth of the well of the station.

In additional features, the station further comprises a first liner and a second liner. The first liner lines an inner sidewall of the well. The second liner lines a second surface of the bottom of the well. The first liner is taller than the object. The second liner is annular with an outer edge contacting the first liner and an inner edge contacting the outer sidewall of the object.

In an additional feature, the inner sidewall of the object is shorter than the outer sidewall of the object and does not contact the second surface of the bottom of the well.

In additional features, the station further comprises a plurality of lift pin assemblies to support the substrate. The object comprises recessed portions on which the lift pin assemblies rest.

In additional features, the well comprises a plurality of openings along a pedestal-facing rim of the well to access the lift pin assemblies. The first liner comprises protrusions extending radially outwardly and covering the openings.

In additional features, the station further comprises a heat shield coupled to a well-facing end of the base portion. The shroud surrounds the heat shield.

In additional features, the well comprises an exhaust port. The station further comprises a first liner and a second liner. The first liner lines the exhaust port. The second liner lines an inner sidewall of the well and mates with the first liner.

In additional features, the station further comprises a third liner lining a pedestal-facing surface of a bottom of the well and mates with the first and second liners.

In additional features, the station further comprises a hollow object disposed in the well. The well and the second liner are greater in height than the hollow object.

In additional features, the third liner is annular with an outer edge contacting the second liner and an inner edge contacting the hollow object.

In additional features, the station further comprises an edge ring disposed around the base portion of the pedestal. The shroud is mounted to the edge ring with a gap maintained between the shroud and the edge ring. The well comprises an inlet. Gases enter the well through the gap and the inlet, flow around the hollow object, and exit the well through the exhaust port.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows a plan view of an example of a substrate processing system (tool) comprising a plurality of stations for processing substrates;

FIG. 2 shows an example of a cross-sectional view of a station of the tool of FIG. 1;

FIG. 3A shows an example of a cross-sectional view of the station of FIG. 2 further comprising a shroud, a wall liner for a well of the station, an annular bottom liner for the well, and a volume reducer for the well according to the present disclosure;

FIG. 3B shows an example of gas flows for the station of FIG. 3A;

FIG. 4A shows an example of a cross-sectional view of the station of FIG. 2 further comprising the shroud, the wall liner, a disc-shaped bottom liner for the well, and without the volume reducer according to the present disclosure;

FIG. 4B shows an example of gas flows for the station of FIG. 4A;

FIG. 5A shows a perspective view of the well of the station of FIG. 2 showing an exhaust port in the well and comprising a port liner for the exhaust port according to the present disclosure;

FIG. 5B shows a perspective view of an example of the port liner according to the present disclosure;

FIG. 6 shows a perspective view of an example of the annular bottom liner for the well according to the present disclosure;

FIGS. 7A and 7B respectively show top and bottom perspective views of the disc-shaped bottom liner for the well according to the present disclosure;

FIG. 8 shows a perspective view of the well comprising the port liners of FIG. 5B and the disc-shaped bottom liner of FIGS. 7A and 7B according to the present disclosure;

FIGS. 9A and 9B respectively show front and back perspective views of a first section of the wall liner according to the present disclosure;

FIGS. 10A and 10B respectively show front and back perspective views of a second section of the wall liner according to the present disclosure;

FIG. 11 shows a perspective view of the well comprising the port liners of FIG. 5B, the disc-shaped bottom liner of FIGS. 7A and 7B, and the wall liners of FIGS. 9A-10B according to the present disclosure;

FIGS. 12A and 12B respectively show top and bottom perspective views of the volume reducer for the well according to the present disclosure;

FIG. 13 shows a perspective view of the well comprising the port liners of FIG. 5B, the annular or disc-shaped bottom liner of FIGS. 6-7B, the wall liners of FIGS. 9A-10B, and the volume reducer of FIGS. 12A and 12B according to the present disclosure; and

FIG. 14 shows an example of the shroud according to the present disclosure.

In the drawings, reference numbers may be reused to identify similar and/or identical elements.

### DETAILED DESCRIPTION

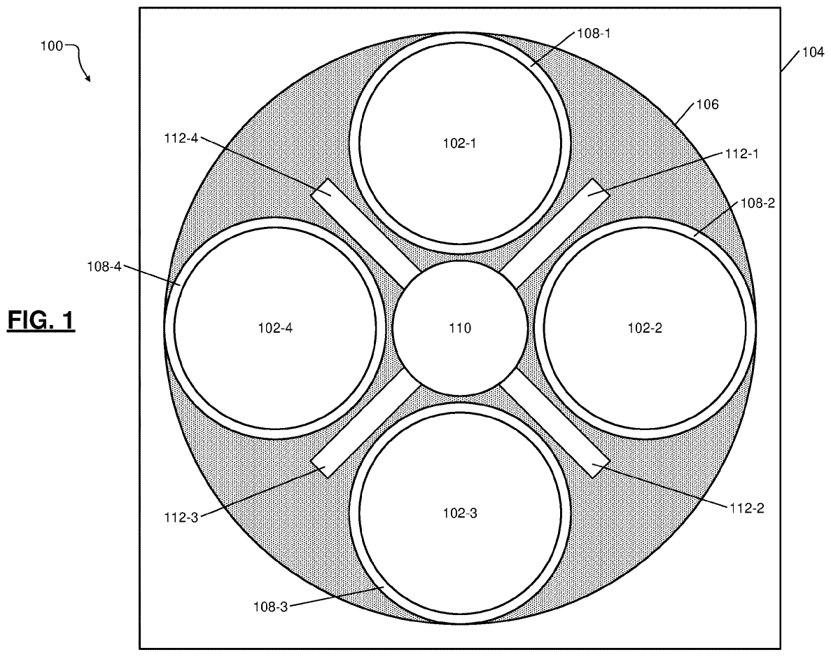

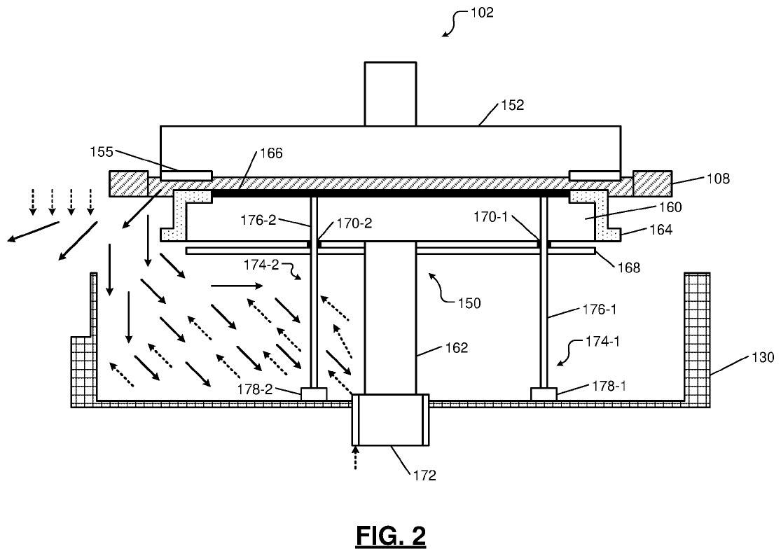

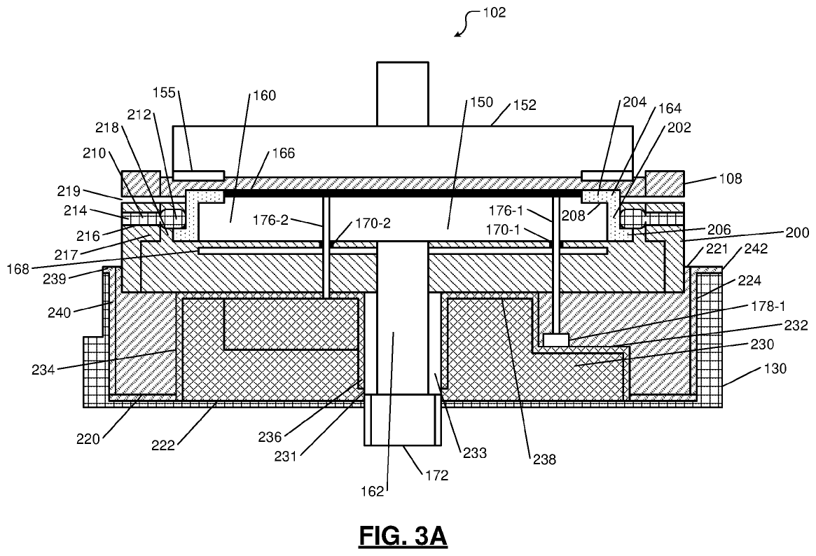

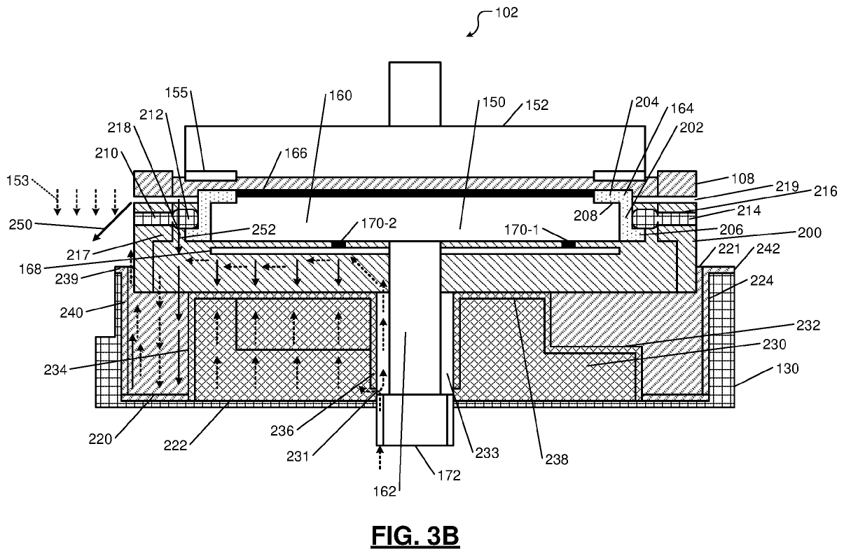

Before describing a shroud and other features of the present disclosure, the problems solved by the present disclosure are described with reference to FIGS. 1 and 2. Thereafter, solutions to the problems provided by the shroud and the other features are described in detail with reference to FIGS. 3A-14.

### Tool

FIG. 1 shows a plan view of an example of a substrate processing system (also called a tool) 100. The tool comprises four stations 102-1, 102-2, 102-3, and 102-4 (collectively the stations 102). While only four stations 102 are shown for illustrative purposes, the tool 100 can comprise N stations, where N is an integer greater than 2. Each station 102 comprises a well in which a pedestal is arranged (both shown in FIG. 2). A top plate 104 and a purge plate 106 are arranged above the stations 102. The top plate 104 and the purge plate 106 comprise openings that are concentric with the wells of the stations 102. A top plate ring (shown at 108-1, 108-2, 108-3, and 108-4; collectively the top plate ring 108) is disposed at a circumference of each opening. A showerhead (shown in FIG. 2) is arranged through the opening above each station 102 to supply process gases and purge gases into the station 102.

During processing, a substrate such as a semiconductor wafer (shown in FIG. 2) is arranged on the pedestal, and process gases and purge gases are supplied through the showerhead to process the substrate. A purge gas (e.g., an inert gas) is supplied through perforated holes in the purge plate 106 to purge the process gases and process byproducts escaping through the top plate ring 108. A spindle 110 is arranged centrally relative to the stations 102 as shown. Robot arms 112-1, 112-2, 112-3, and 112-4 (collectively the robot arms 112) are attached to a periphery of the spindle 110. The spindle 110 moves the robot arms 112 laterally in a plane parallel to the top plate 104 and the purge plate 106. An end effector (not shown) moves a substrate from a load lock (not shown) into the stations 102-1. The spindle 110 and the robot arms 112 move the substrate between the stations 102 through transfer ports (not shown) located near top ends of the stations 102.

### Station

FIG. 2 shows an example of a cross-sectional view of one of the stations 102 without the shroud and liners of the present disclosure. The station 102 comprises a well 130. The well 130 is cylindrical and hollow. For example, the well 130 has a shape of an open cylindrical vessel or container. The station 102 comprises a pedestal 150 and a showerhead 152. The pedestal 150 is arranged in the well 130. The pedestal 150 comprises a base portion 160 and a stem portion 162. The stem portion 162 extends vertically downwards from a center region of the base portion 160. The base portion 160 and the stem portion 162 are cylindrical. The base portion 160 has a greater diameter than the stem portion 162. An edge ring 164 is arranged around the base portion 160. A substrate 166 is arranged on the top surface of the base portion 160. The edge ring 164 surrounds the substrate 166. An inner diameter (ID) of the edge ring and an outer diameter (OD) of the base portion 160 are greater than the diameter of the substrate 166. During processing, the base portion 160 is heated, and process gases and purge gases are supplied during respective process cycles by the showerhead 152.

The showerhead 152 comprises an edge ring 155. The edge ring 155 is disposed in a recess around the OD of the showerhead 152 at a lower end of the showerhead 152. The edge ring 155 surrounds a substrate-facing surface (faceplate) of the showerhead 152. The edge ring 155 and the showerhead 152 have the same OD. The edge ring 155 is thicker than a depth of the recess and extends slightly below the faceplate of the showerhead 152. As a result, while the faceplate of the showerhead 152 is flush (level) with a top edge of the top plate ring 108, the bottom of the edge ring 155 extends slightly below the top edge of the top plate ring 108. The edge ring 155 is located above the edge ring 164.

A heat shield 168 is coupled to a lower surface of the base portion 160 using fasteners 170-1, 170-2 (collectively the fasteners 170). The heat shield 168 extends radially from a top end of the stem portion 162 to the OD of the base portion 160. An actuator 172 is attached to a lower end of the stem portion 162 of the pedestal 150. The actuator 172 moves the pedestal 150 vertically to adjust a gap between the substrate 166 and the showerhead 152. The heat shield 168 moves with the pedestal 150. A gap is maintained between the edge rings 155 and 174 even when the pedestal 150 is moved vertically relative to the showerhead 152.

Lift pin assemblies 174 (shown at 174-1 and 174-2 with 174-3 being invisible in the view shown; collectively the lift pin assemblies 174) are arranged in the well 130 of the station 102. Each lift pin assembly 174 comprises a lift pin 176 (shown at 176-1 and 176-2 with 176-3 being invisible in the view shown; collectively the lift pins 176). Each lift pin 176 is attached to a respective base portion 178 (shown at 178-1 and 178-2 with 178-3 being invisible in the view shown; collectively the base portions 178). The base portions 178 serve as counterweights and hold respective lift pins 176 stationary. Distal ends of the lift pins 176 pass through the fasteners 170 of the heat shield 168 and through the base portion 160 of the pedestal 150 and extend up to the top surface of the base portion 160.

To load the substrate 166 into the station, the actuator 172 lowers the pedestal 150. When the pedestal 150 is lowered, the lift pins 176 protrude from the top surface of the base portion 160. The robot arm 112 (shown in FIG. 1) loads the substrate 166 into the station 102 onto the lift pins 176 and retracts. The substrate 166 rests on the lift pins 176. Thereafter, the actuator 172 lifts the pedestal 150. The lift pins 176, being stationary and held by the counterweight of the base portions 178, recess into the base portion 160. The substrate 166 rests on the top surface of the base portion 160 and is ready to be processed using the process gases supplied by the showerhead 152.

### Problems Solved by Invention

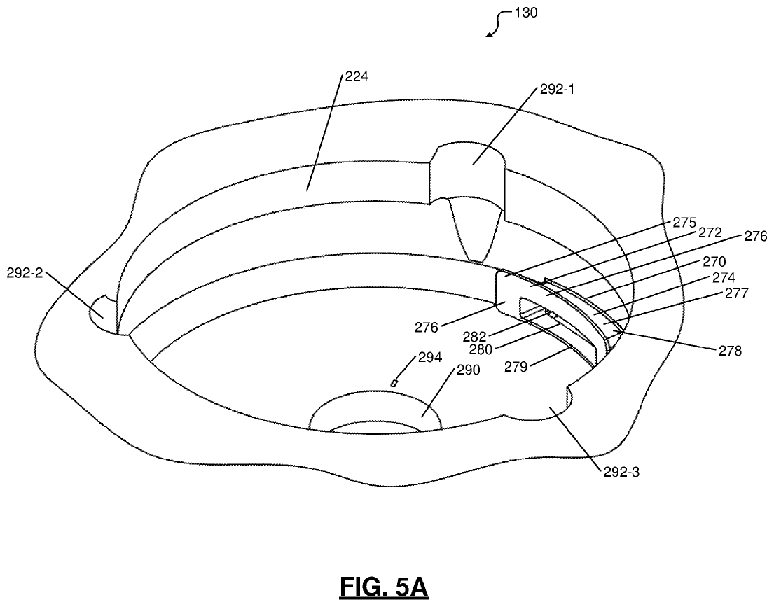

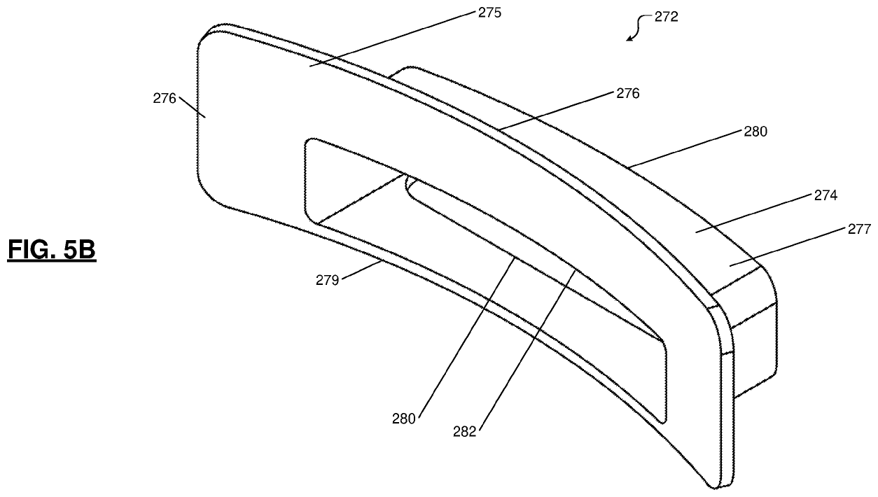

The process gases and process byproducts typically escape through the top plate ring 108 (e.g., through the gap between the edge rings 155 and 164) towards adjacent stations 102 and into the well 130 of the station 102. The flow of these escaping process gases (e.g., unreacted process gases) and process byproducts (collectively called contaminants) are shown by solid arrows. The flow of the contaminants from one station 102 to another station 102 is called crosstalk between the stations 102. The purge gas supplied through the purge plate 106 is insufficient to prevent the contaminants from contaminating the adjacent stations 102 and the well 130 of the station 102. To dilute the contaminants in the well 130, in addition to the purge gas supplied by the showerhead 152, a purge gas (e.g., an inert gas) is also supplied into the well 130 from an assembly coupled to a lower end of the stem portion 162 of the pedestal 150. For example, the assembly may comprise bellows (not shown) arranged around the actuator 172. The flow of the purge gases is shown by dotted arrows. The diluted contaminants exit the well 130 through a pair of exhaust ports (shown in FIG. 5A) in the well 130 into an exhaust system of the tool 100 (not shown). Throughout the present disclosure, for simplicity, the flow of the contaminants and the purge gases is shown only on one side of the station 102. It is understood that similar flow occurs all around the station 102.

Currently, the crosstalk between the stations 102 is reduced by supplying the purge gas supplied through the purge plate 106. The purge gas supplied through the purge plate 106 forms a curtain of the purge gas around the showerhead 152. The curtain of the purge gas acts as a shield between the stations 102. A pressure difference between the stations 102 and/or between the station 102 and a cover region (space between two stations 102, comprising the top plate 104 and the purge plate 106) can affect the functionality of the curtain gas. Further, the process byproducts that diffuse into the well 130 require more purge time to purge the diffused byproducts from the well 130 through the exhaust ports, which can affect throughput of the tool 100. Consequently, the contaminants can deposit on the cover region, the transfer ports, and in the well 130 of the station 102. For some reactants used in some processes, repeated cleaning of the station 102 is insufficient to clean the contaminants. Further, some of the contaminants create nucleation sites on inner and other surfaces of the tool 100. The nucleation sites further build up contamination causing formation of undesirable contaminant layers on the tool surfaces.

### Overview of Invention

To solve the above problems, the present disclosure provides a shroud around the pedestal 150 and wall liners around a sidewall and bottom of the well 130 to reduce the crosstalk between the stations 102 and to reduce the contamination in the well 130. The present disclosure further provides a volume reducer that is disposed in the well 130 to reduce the volume of the well 130, which reduces the contaminants in the well 130 and reduces the time to purge the contaminants from the well 130 into the exhaust system during purge cycles of the process. The shroud, the walls liners, and the volume reducer are described below in detail with reference to FIGS. 3A-14.

Briefly, the shroud is a hollow cylindrical element that is attached to the base portion 160 of the pedestal 150. The shroud surrounds the base portion 160 of the pedestal 150 and extends vertically downwards from the base portion 160 of the pedestal 150 towards the well 130. The shroud moves with the pedestal 150. The shroud can be made of a metallic material (e.g., an alloy) or a nonmetallic material (e.g., a ceramic material) depending on temperature requirements of the process performed in the station 102. The shroud creates a microvolume around the showerhead 152 relative to the top plate ring 108 due to a small gap maintained between the shroud and the top plate ring 108. Due to the microvolume and the purge gas supplied from the showerhead 152 during purge cycles of a process, the flow of process byproducts into the cover region can be reduced and can be diverted into the well 130 instead. The process byproducts diverted into the well 130 are diluted by the purge gas supplied from the showerhead 152 and from the lower end of the stem portion 162 of the pedestal 150. The volume of the well 130 can be reduced by inserting a volume reducer in the well 130 as explained below. The purge gas supplied from the lower end of the stem portion 162 flows around the volume reducer. The process byproducts diluted in the well 130 exit through the exhaust ports in the well 130 into the exhaust system of the tool. Since the process byproducts are restricted from flowing into the cover region due to the microvolume, the process byproducts cannot contaminate the cover region and the transfer port of the station 102. Further, the crosstalk between the stations 102 is minimized since only a minimal amount of contaminants escaping the top plate ring 108 can flow to the adjacent stations 102.

Further, as explained below in detail, vertical wall liners extend along an ID of the sidewall of the well 130 from the bottom of the well to the top of the well. Top portions of the wall liners surround a bottom portion of the shroud even when the shroud moves vertically with the pedestal 150. A small gap is maintained between an ID of the top portions of the wall liners and an OD of the bottom portion of the shroud creating a microvolume therebetween. A pressure difference exists between the curtain of the purge gas supplied from the purge plate 106 outside the well 130 and the purge gas supplied into the well 130 from the bottom portion of the stem portion 162 of the pedestal 150. Due to the pressure difference and the microvolume between the wall liners and the shroud, the process byproducts diluted in the well 130 do not exit through the gap between the wall liners and the shroud and do not contaminate the adjacent stations 102. Further, the contamination in the well 130 is significantly reduced by filling the space available in the well 130 with the volume reducer, which reduces the volume of the well 130. Due to the reduction in the well volume, the purge time to remove the contaminants from the well 130 during purge cycles of the process is also reduced, which increases throughput.

Thus, the shroud around the pedestal 150 acts as a physical barrier to process byproducts, diverts the flow of process byproducts to the well 130 of the station 102, and restricts the flow of process byproducts to the cover region and to the neighboring stations 102. The shroud creates a microvolume circumferentially around the showerhead 152 relative to the top plate ring 108. The gap between the shroud and the top plate ring 108 is optimized empirically to restrict the flow of process byproducts through the gap. The gap can accommodate manufacturing and assembly tolerances of the shroud and the top plate ring 108. The shroud also creates a microvolume radially with the wall liners of the well 130, which prevents backflow of the process byproducts from the well 130 to the cover region and to the adjacent stations 102. Instead, the diverted process byproducts occupy the volume in the well 130, which is reduced by the volume reducer. The volume reducer rests on the bottom of the well, is surrounded by the wall liners, and has a height that is less than a height of the wall liners. The volume reducer not only prevents contamination in the well 130 but also reduces the purge time required to purge the contaminants from the reduced volume of the well 130. The heat shield 168 shields the volume reducer and prevents the heat from the base portion 160 of the pedestal 150 from heating the volume reducer. These and other features of the present disclosure are described below in detail.

### Organization of Disclosure

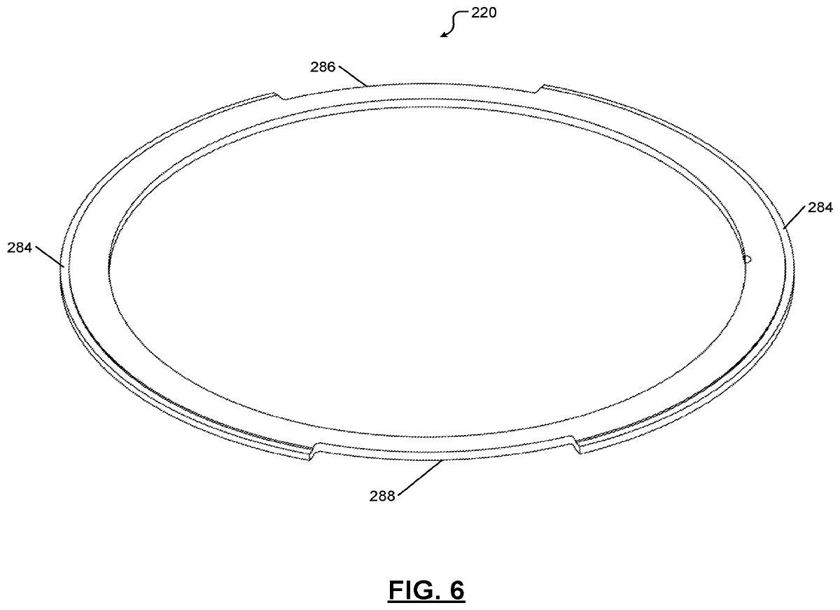

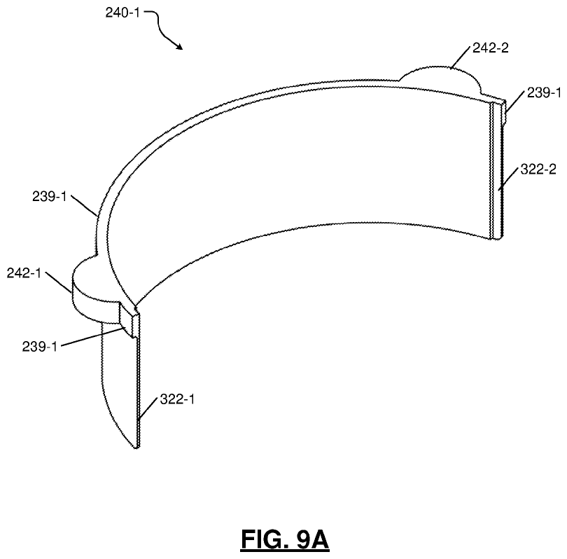

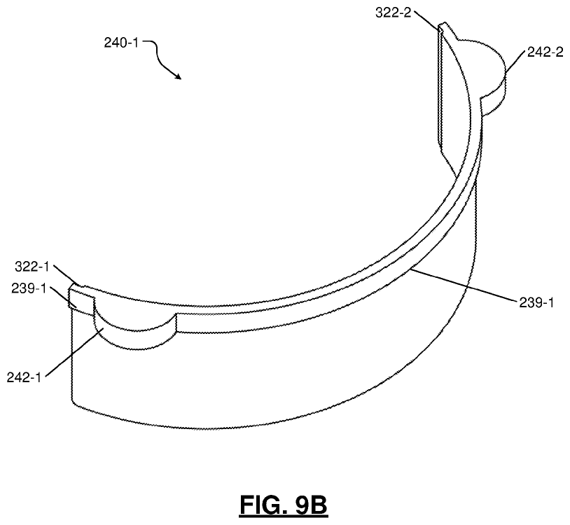

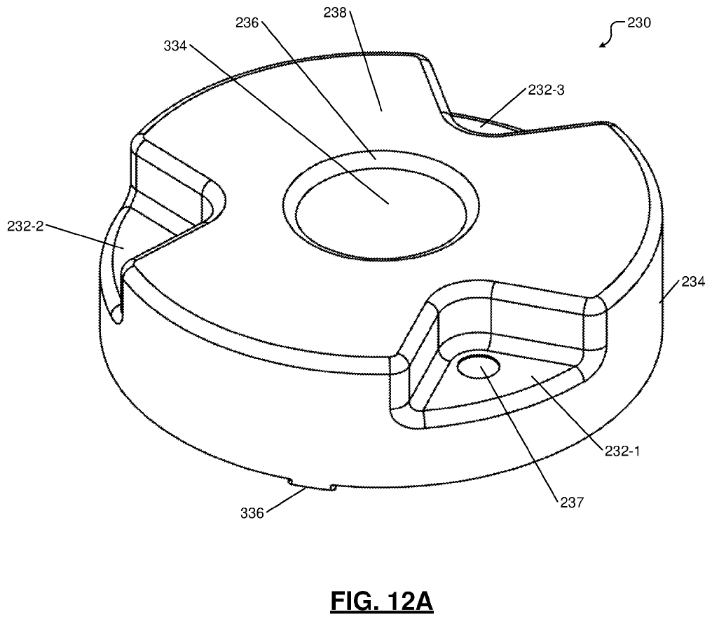

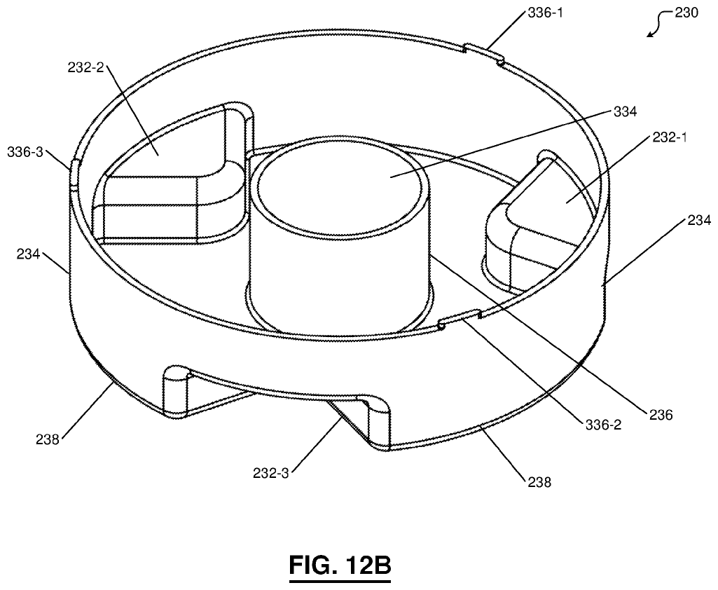

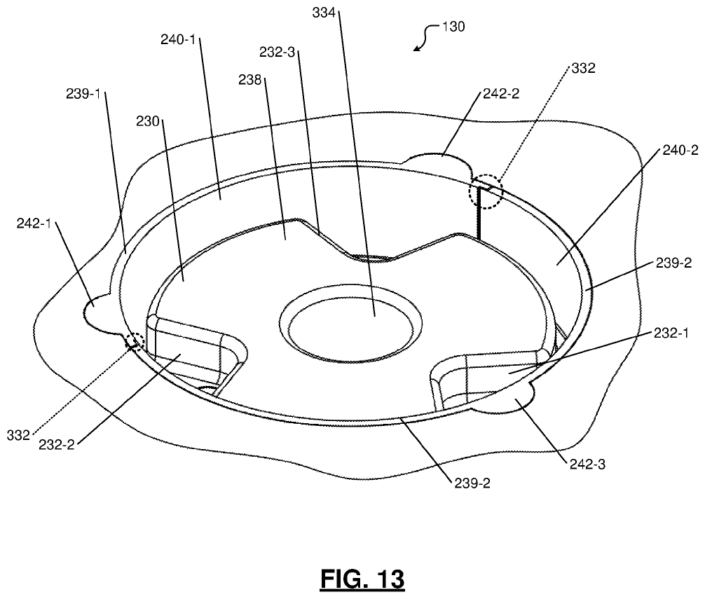

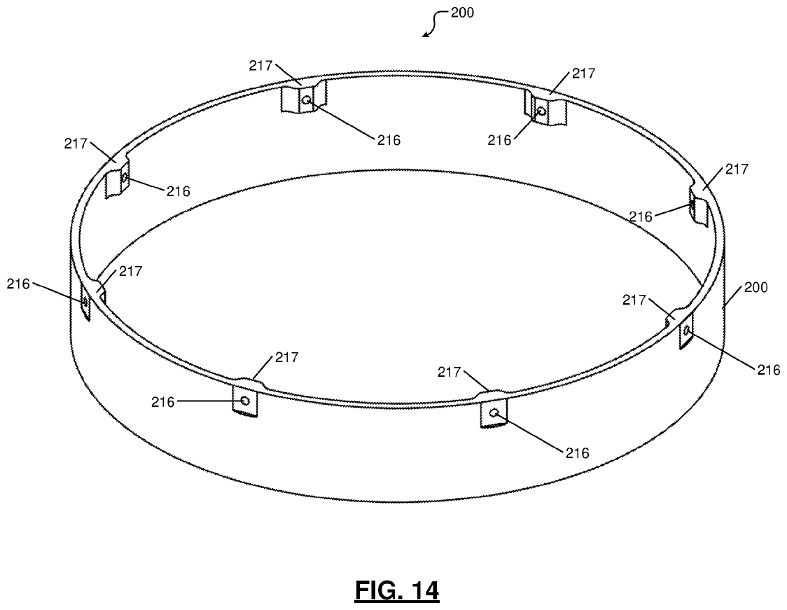

The remainder of the present disclosure is organized as follows. Various cross-sectional views of the station comprising the shroud and various liners and associated gas flows are shown and described with reference to FIGS. 3A-5B. The station well, exhaust port, and a port liner for the exhaust port are shown and described with reference to FIGS. 5A and 5B. Different types of bottom liners for the station well are shown and described with reference to FIGS. 6-9. The wall liners for the station well are shown and described with reference to FIGS. 9A-11. The volume reducer is shown and described with reference to FIGS. 12A-13. The shroud is shown and described with reference to FIG. 14.

Station With Shroud and Liners

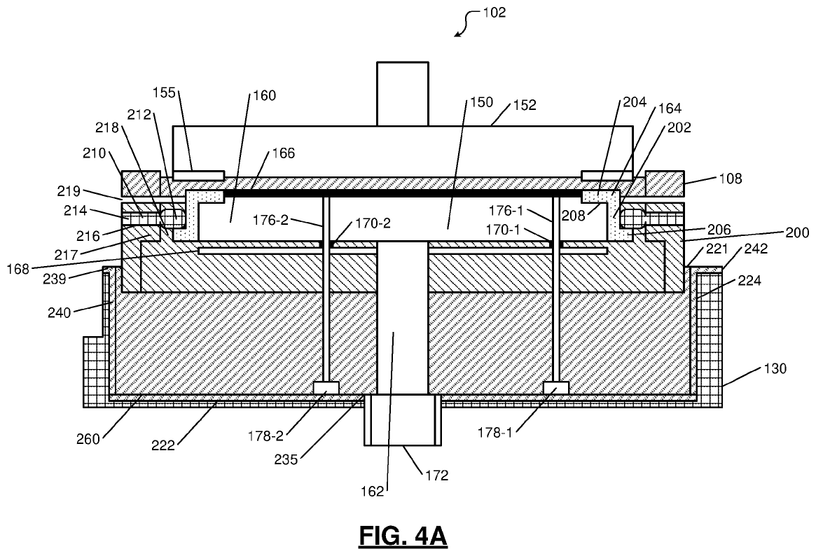

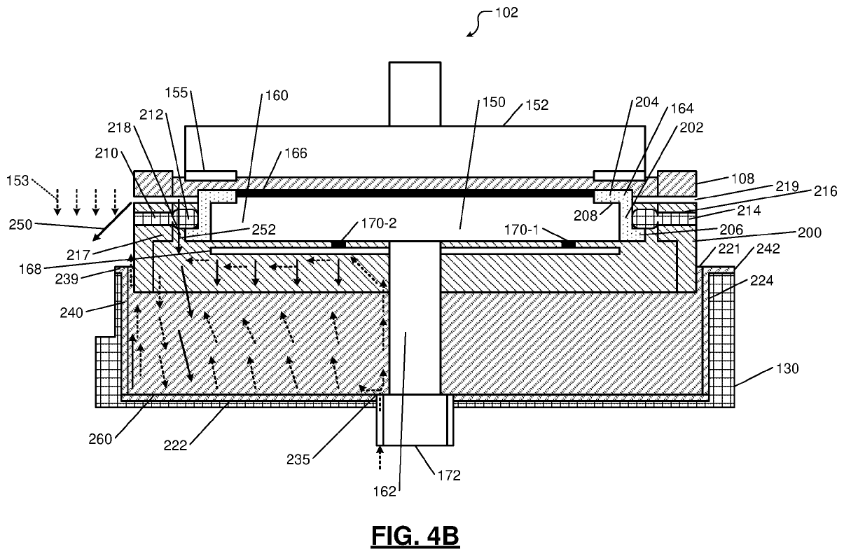

FIGS. 3A-5B show examples of a station with the shroud and various liners. The bottom liner for the station well can be annular or disc-shaped. The annular bottom liner is used with the volume reducer as shown and described with reference to FIG. 3A. The disc-shaped bottom liner can be used with or without the volume reducer. An example of a station that uses the disc-shaped bottom liner without the volume reducer is shown and described with reference to FIG. 4A. Gas flows for the two configurations (with and without volume reducer and corresponding bottom liners) are shown and described with reference to FIGS. 3B and 4B. To simplify illustration of the gas flows, the lift pin assemblies shown in FIGS. 3A and 4A are omitted from FIGS. 3B and 4B.

FIG. 3A shows a cross-sectional view of a station (e.g., the station 102 shown in FIGS. 1 and 2) comprising the shroud for pedestal 150 and liners for the well 130, including the annular bottom liner for the well 130. Elements shown and described with reference to FIG. 2 are not described again for brevity.

The station 102 comprises a shroud 200. The shroud 200 is a hollow, skirt-like, cylindrical element that is attached to the base portion 160 of the pedestal 150. The shroud 200 surrounds (skirts) the base portion 160. The shroud 200 extends vertically downwards from a circumference (OD) of the base portion 160 towards the well 130. The shroud 200 extends below the heat shield 168. The shroud 200 and the pedestal 150 are coaxial. A height of the shroud 200 is greater than a height of the base portion 160. The height of the shroud 200 is a sum of the height of the base portion 160 and at least a part of the stem portion 162. The height of the shroud 200 is less than the height of the pedestal 150. That is, the height of the shroud 200 is less than sum of the heights of the base portion 160 and the stem portion 162. The shroud 200 is attached to the base portion 160 via the edge ring 164 as follows.

The edge ring 164 is arranged around the circumference (OD) of the base portion 160. The edge ring 164 comprises a cylindrical portion 202, a first flange 204, and a second flange 206. The cylindrical portion 202 surrounds the OD of the base portion 160. The first flange 204 extends radially inwards from an upper end of the cylindrical portion 202. The second flange 206 extends radially outwards from a lower end of the cylindrical portion 202.

An upper surface of the base portion 160 comprises a recess 208. The recess 208 extends radially inwards from the circumference (OD) of the upper surface of the base portion 160. The first flange 204 rests on the recess 208. A depth (width) of the recess 208 matches a length of the first flange 204. The cylindrical portion 202 is in direct contact with the OD of the base portion 160. An ID of the cylindrical portion 202 matches the OD of the base portion 160.

A plurality of pins 210 is used to couple the shroud 200 to the base portion 160. Each pin 210 comprises a head 212 and a shaft 214 that extends from the head 212. The heads 212 of the pins 210 rest on the second flange 206 of the edge ring 164. The shafts 214 of the pins 210 are inserted into corresponding holes 216 arranged along an upper end of the shroud 200. The holes 216 are drilled through corresponding mounting locations 217 that protrude radially inwardly from the ID of the shroud 200 (see FIG. 14).

The heads 212 of the pins 210 are larger in diameter than the shafts 214 of the pins 210. The length of the heads 212 is such that when the shafts 214 are inserted into the holes 216 in the shroud 200, a small gap 218 is maintained between an ID of the shroud 200 and an OD (edge) of the second flange 206. The use of the small gap 218 is explained below with reference to FIG. 3B.

The shroud 200, the mounting locations 217, and the holes 216 are shown in further detail in FIG. 14. When the shroud 200 is mounted to the edge ring 164, a small gap 219 is maintained between the upper end of the shroud 200 and the top plate ring 108. The shroud 200 creates a microvolume around the showerhead 152 relative to the top plate ring 108 due to the small gap 219 maintained between the shroud 200 and the top plate ring 108. The use of the small gap 219 is explained below with reference to FIG. 3B.

An annular bottom liner 220 (hereinafter the bottom liner 220) is arranged on an upper surface 222 of the bottom of the well 130. While the bottom liner 220 is shown as a single piece throughout the present disclosure, the bottom liner 220 can comprise multiple arcuate segments that can be joined together to form the annular bottom liner 220. An OD of the bottom liner 220 matches an ID of the well 130 (i.e., an ID of an inner sidewall 224 of the well 130). An ID of the annular bottom liner 220 matches an OD of a volume reducer 230 disposed in the well 130. The annular bottom liner 220 is shown and described below in detail with reference to FIG. 6.

The volume reducer 230 is shown and described below in detail with reference to FIGS. 12A-13. Briefly, the volume reducer 230 is generally cylindrical although other shapes may be used. The volume reducer 230 has an outer sidewall 234, an inner sidewall 236, and an upper surface 238. The upper surface 238 extends between the outer and inner sidewalls 234, 236. The volume reducer 230 is open (i.e., not enclosed) at the bottom. The volume reducer 230 is hollow. The volume reducer 230 rests on the upper surface 222 of the bottom of the well 130. The inner sidewall 236 of the volume reducer 230 surrounds the stem portion 162 of the pedestal 150. The volume reducer 230 generally fills more than half of the volume of the well 130 and reduces the volume of the well 130.

An ID of the volume reducer 230 (i.e., an OD of the inner sidewall 236) is greater than an OD of the stem portion 162 of the pedestal 150. As a result, a small gap 233 is maintained between the ID of the volume reducer 230 (i.e., the OD of the inner sidewall 236) and the OD of the stem portion 162 of the pedestal 150. Gas flows through the small gap 233 are shown and described below with reference to FIG. 3B.

An OD of the volume reducer 230 (i.e., an OD of the outer sidewall 234) matches the ID of the bottom liner 220. A length (height) of the inner sidewall 236 the volume reducer 230 is slightly less than a length (height) of the outer sidewall 234 the volume reducer 230. Accordingly, when the volume reducer 230 rests on the upper surface 222 of the bottom of the well 130, a lower end of the outer sidewall 234 contacts the upper surface 222 of the bottom of the well 130 but a lower end of the inner sidewall 236 does not contact the upper surface 222 of the bottom of the well 130. As a result, an opening 231 exists between the lower end of the inner sidewall 236 and the upper surface 222 of the bottom of the well 130. Gas flows through the opening 231 are shown and described below with reference to FIG. 3B.

A height of the volume reducer 230 is less than a depth (height) of the well 130. The height of the volume reducer 230 is a distance between the upper surface 222 of the bottom of the well 130 and the upper surface 238 of the volume reducer 230. The height of the volume reducer 230 is also the length (height) of the outer sidewall 234 of the volume reducer 230. The height of the volume reducer 230 is less than a height of the wall liners (described below). The outer sidewall 234 of the volume reducer 230 comprises a plurality of stepped (recessed) portions 232 that extend radially inwards from the OD of the outer sidewall 234 of the volume reducer 230. The base portions 178 of the lift pin assemblies 174 rest on the recessed portions 232.

Two semi-circular wall liners are disposed along the inner sidewall 224 of the well 130. The wall liners are shown and described in detail with reference to FIGS. 9A-11. While two wall liners are shown and described for illustrative purposes throughout the present disclosure, it is understood that a single cylindrical wall liner may be used instead. Alternatively, a wall liner comprising a plurality of arc-shaped elements may be used to fully line the inner sidewall 220 of the well 130.

In the views shown in FIGS. 3A-4B, only one of the two semi-circular wall liners is visible and is shown at 240. The wall liner 240 extends vertically upwards from the upper surface 222 of the bottom of the well 130 to an upper end 226 of the well 130 along the inner sidewall 224 of the well 130. The wall liner 240 lines (covers) the entire inner sidewall 224 of the well 130. An OD of the wall liner 240 matches the ID of the well 130 (i.e., the ID of an inner sidewall 224 of the well 130). A lower end of the wall liner 240 rests on an upper surface of the bottom liner 220 near the OD of the bottom liner 220. Alternatively, while not shown, the lower end of the wall liner 240 may extend to and rest on the upper surface 222 of the bottom of the well 130, and the OD of the bottom liner 220 may match an ID of the wall liner 240.

An upper end of the wall liner 240 extends radially outwardly forming a flange 239. The flange 239 rests on the upper end 226 of the well 130. Additionally, the upper end of the wall liner 240 comprises a plurality of protrusions 242 (only one protrusion 242 is visible in the view shown). The protrusions 242 extend radially outwards from the upper end of the wall liner 240. The protrusions 242 extend farther than the flange 239. The protrusions 242 rest on the upper end 226 of the well 130. The protrusions 242 cover respective access openings (see FIGS. 5A and 9A-11) along the upper end 226 of the well 130. The flange 239 and the protrusions 242 are shown and described in further detail with reference to FIGS. 9A-11.

The height of the wall liner 240 is about the same as the height (depth) of the well 130. The height of the wall liner 240 is greater than the height of the volume reducer 230. The height of the shroud 200 is less than the heights of each of the wall liner 240, the well 130, and the volume reducer 230. The ID of the wall liner 240 is slightly greater than the OD of the shroud 200. As a result, a small gap 221 is maintained between the OD of the shroud 200 and the ID of the wall liner 240. Gas flows through the small gap 221 are shown and described below with reference to FIG. 3B. Additional features of the wall liner 240 are shown and described below with reference to FIGS. 9A-11.

The wall liner 240 is substantially perpendicular to the bottom liner 220. The wall liner 240 is substantially parallel to the shroud 200. The bottom liner 220 is also substantially perpendicular to the shroud 200. The shroud 200, the bottom liner 220, the volume reducer 230, the wall liner 240, the well 130, the pedestal 150, and the showerhead 152 are concentric. The term substantially takes into account any slight tilt of the pedestal 150 relative to a vertical axis and any slight curvature of the upper surface 222 of the bottom of the well 130.

FIG. 3B shows gas flows for FIG. 3A. Flow of the purge gas is shown using dotted arrows. Flow of process gases and byproducts are shown using solid arrows. For simplicity of illustration, the gas flows are shown only on one side of the cross-sectional view of the station 102. It is understood that similar gas flows occur throughout the station 102. To clearly illustrate the gas flows, the lift pin assemblies 174 shown in FIG. 3A are omitted from FIG. 3B but are presumed to be present in FIG. 3B.

As described above, a microvolume is created by the small gap 219 maintained between the shroud 200 and the top plate ring 108. The purge gas is supplied from the showerhead 152 during purge cycles of a process as shown at 153. Due to the microvolume and the purge gas, the process byproducts are prevented from flowing into the cover region as shown at 250 and are diverted into the well 130 through the small gap 218 as shown at 252.

Additionally, as described above, the purge gas is also supplied from under the lower end of the stem portion 162 of pedestal 150. The purge gas flows through the small gap 233 and flows around the volume reducer 230 as shown. The purge gas also flows into the volume reducer 230 through the opening 231 as shown, which prevents the process byproducts from contaminating the inside of the volume reducer 230.

The process byproducts diverted into the well 130 are diluted by the purge gas supplied from the showerhead 152 and by the purge gas supplied from under the lower end of the stem portion 162 of the pedestal 150. Further, due to the pressure difference between inside and outside the well 130, the process byproducts diluted in the well 130 are prevented from escaping through the small gap 221 maintained between the OD of the shroud 200 and the ID of the wall liner 240. Instead, the process byproducts diluted in the well 130 exit through the exhaust ports in the well 130 (shown in FIG. 5A) into the exhaust system of the tool.

Since the process byproducts are restricted from flowing into the cover region due to the microvolume created by the small gap 219 between the shroud 200 and the top plate ring 108, the process byproducts cannot contaminate the cover region and the transfer port of the station 102 (shown in FIG. 5A). Further, the crosstalk between the stations 102 is minimized since only a minimal amount of contaminants escaping the top plate ring 108 can flow to the adjacent stations 102. The crosstalk is further reduced due to the microvolume created by the small gap 221 between the OD of the shroud 200 and the ID of the wall liner 240. Furthermore, the contamination in the well 130 is prevented by reducing the volume of the well 130 using the volume reducer 230. Due to the reduction in the well volume, the purge time to remove the contaminants from the well 130 during purge cycles of the process is also reduced, which increases process throughput.

Thus, the shroud 200 around the pedestal 150 acts as a physical barrier to process byproducts, diverts the flow of process byproducts to the well 130 of the station 102, and restricts the flow of process byproducts to the cover region and to the neighboring stations 102. The shroud 200 creates a microvolume circumferentially around the showerhead 152 relative to the top plate ring 108. The small gap 219 between the shroud 200 and the top plate ring 108 is optimized empirically to restrict the flow of process byproducts through the small gap 219. The small gap 219 can accommodate manufacturing and assembly tolerances of the shroud 200 and the top plate ring 108.

The shroud 200 also creates a microvolume radially with the wall liners 240 of the well 130, which prevents backflow of the process byproducts from the well 130 to the cover region and to the adjacent stations 102 through the small gap 221 between the shroud 200 and the wall liner 240. Instead, the diverted process byproducts occupy the volume in the well 130, which is reduced by the volume reducer 230 as explained above. Thus, the volume reducer 230 not only prevents contamination in the well 130 but also reduces the purge time required to purge the contaminants from the reduced volume of the well 130. The heat shield 168 shields the volume reducer 230 and prevents the heat from the base portion 160 of the pedestal 150 from heating the volume reducer 230.

FIG. 4A shows a cross-sectional view of a station (e.g., the station 102 shown in FIGS. 1 and 2) comprising the shroud 200, the wall liners 240, and a disc-shaped bottom liner for the well 130. The only differences between FIGS. 4A and 3A are that FIG. 3A uses the annular bottom liner 220 and the volume reducer 230 while FIG. 4A uses the disc-shaped bottom liner and does not use the volume reducer 230 (although the volume reducer 230 may be used with disc-shaped bottom liner). Accordingly, only the differences between FIGS. 3A and 4A due to the different bottom liner and the absence of the volume reducer are described. All other elements shown and described with reference to FIGS. 2 and 3A are not described again for brevity.

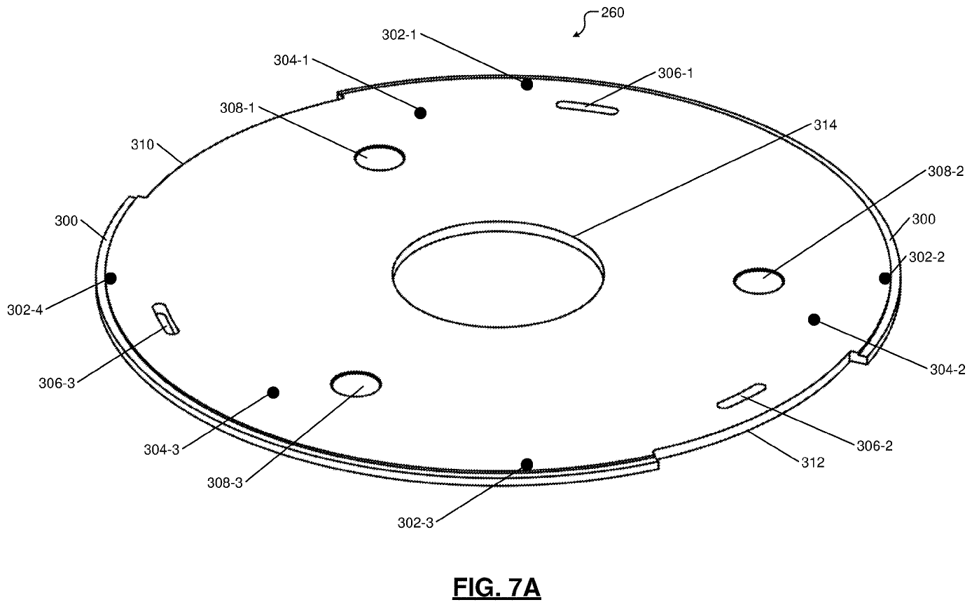

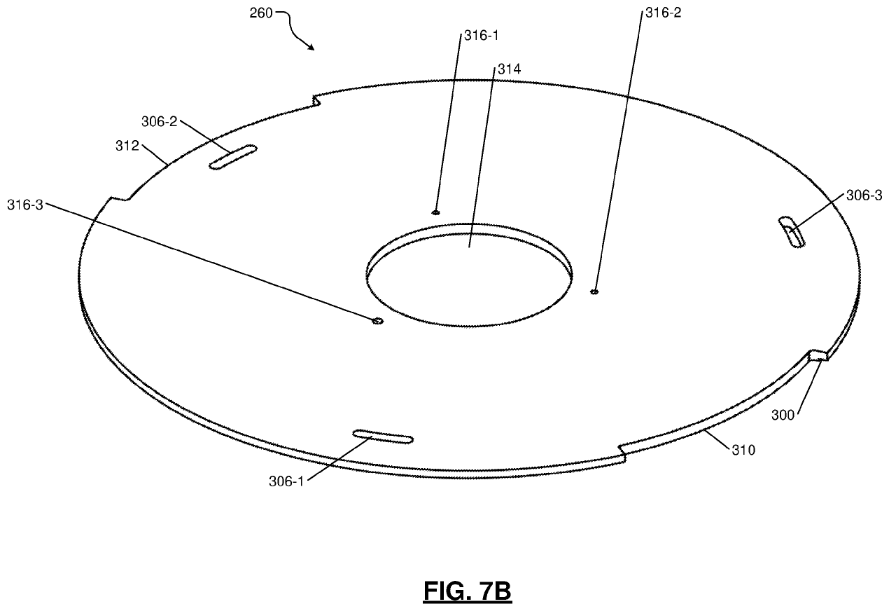

In FIG. 4A, a disc-shaped bottom liner 260 (hereinafter the bottom liner 260) is arranged on the upper surface 222 of the bottom of the well 130. While the bottom liner 260 is shown as a single piece throughout the present disclosure, the bottom liner 260 can comprise multiple segments that can be joined together to form the disc-shaped bottom liner 260. The disc-shaped bottom liner 260 is shown and described below in detail with reference to FIGS. 7A and 7B.

Briefly, the bottom liner 260 extends radially from near the OD of the stem portion 162 of the pedestal 150 to the ID of the well 130 (i.e., the ID of an inner sidewall 224 of the well 130). An OD of the bottom liner 260 matches the ID of the well 130 (i.e., the ID of an inner sidewall 224 of the well 130). An ID of the bottom liner 260 is slightly greater than the OD of the stem portion 162 of the pedestal 150. An opening 235 exists between the ID of the bottom liner 260 and the upper surface 222 of the bottom of the well 130. Gas flows through the opening 235 are shown and described below with reference to FIG. 4B. The base portions 178 of the lift pin assemblies 174 rest on an upper surface of the bottom liner 260.

The lower end of the wall liner 240 rests on an upper surface of the bottom liner 260 near the OD of the bottom liner 260. Alternatively, while not shown, the lower end of the wall liner 240 may extend to and rest on the upper surface 222 of the bottom of the well 130, and the OD of the bottom liner 260 may match the ID of the wall liner 240.

The wall liner 240 is perpendicular to the bottom liner 260. The bottom liner 260 is also perpendicular to the shroud 200. The shroud 200, the bottom liner 260, the wall liner 240, the well 130, the pedestal 150, and the showerhead 152 are concentric.

FIG. 4B shows gas flows for FIG. 4A. As in FIG. 3B, the flow of the purge gas is shown using dotted arrows, and the flow of process gases and byproducts are shown using solid arrows. For simplicity of illustration, the gas flows are shown only on one side of the cross-sectional view of the station 102. It is understood that similar gas flows occur throughout the station 102. To clearly illustrate the gas flows, the lift pin assemblies 174 shown in FIG. 4A are omitted from FIG. 4B but are presumed to be present in FIG. 4B. Only the differences in gas flows due to the absence of the volume reducer in FIG. 4B are described. All other description of FIG. 3B that applies to FIG. 4B is not repeated for brevity. If the volume reducer 230 is used with the disc-shaped bottom liner 260, the gas flows in FIG. 4B will be similar to those shown and described with reference to FIG. 3B.

The purge gas supplied from under the lower end of the stem portion 162 of pedestal 150 flows through the opening 235 and through the volume of the well 130 as shown, which prevents the process byproducts from contaminating the inside of the well 130. The process byproducts are diverted into the well 130 as described above with reference to FIG. 3B. The process byproducts diverted into the well 130 are diluted and exhausted through the exhaust ports in the well 130 (shown in FIG. 5A) into the exhaust system of the tool as described above with reference to FIG. 3B. The remaining description of FIG. 3B minus the references to the volume reducer applies equally to FIG. 4B and is therefore not repeated for brevity.

### Station Well and Port Liner

FIGS. 5A-5B show the station well, the exhaust port, and the port liner for the exhaust port. FIG. 5A shows the well 130 without the wall liners 240, the volume reducer 230, and the bottom liners 220, 260. The well 130 comprises two exhaust ports located diametrically opposite to each other. In the view shown in FIG. 5A, only one exhaust port is visible and shown. The port liner is shown and described in detail with reference to FIG. 5B. Both FIGS. 5A and 5B should be referred to when reading the description of the port liner.

In FIG. 5A, an exhaust port 270 is located within the sidewall 224 of well 130. The exhaust port 270 is located adjacent to (along) the upper surface 222 of the bottom of the well 130. A port liner 272 is inserted into the exhaust port 270. The port liner 272 is shown and described in further detail with reference to FIG. 5B. The port liner 272 lines (i.e., covers) the exhaust port 270. The port liner 272 prevents contamination of the exhaust port 270 due to the process byproducts that are exhausted through the exhaust port 270 into the exhaust system of the tool as described above with reference to FIGS. 3B and 4B.

The well 130 further comprises access openings 292-1, 292-2, and 292-3 (collectively the access openings 292) along the circumference on the upper end 226 of the sidewall 224 of the well 130. The lift pin assemblies 174 can be accessed through the access openings 292. As shown and described with reference to FIGS. 9A-11, the wall liners 240 comprise the protrusions 242 on the upper ends of the wall liners 240 that cover the access openings 292. By covering the access openings 292, the protrusions 242 prevent contaminants from entering into the well 130 via the access openings 292.

The well 130 further comprises an opening 290 at the center of the upper surface 222 of the bottom of the well 130. The stem portion 162 of the pedestal 150 fits into the opening 290. The well 130 also comprises holes 294 (only one hole 294 is visible in the view shown) on the upper surface 222 of the bottom of the well 130. Corresponding locator pins on a bottom surface of the bottom liner 260 (shown and described with reference to FIGS. 7A and 7B) fit into the holes 294.

FIG. 5B shows the port liner 272 is further detail. Some of the reference numerals described below are shown in FIG. 5A. The port liner 272 comprises a first portion 274 that fits into and around a perimeter of the exhaust port 270. The exhaust port 270 and the first portion 274 are generally rectangular. A first end 280 of the first portion 274 extends laterally through the exhaust port 270 in a radially outward direction from the sidewall 224 of the well 130.

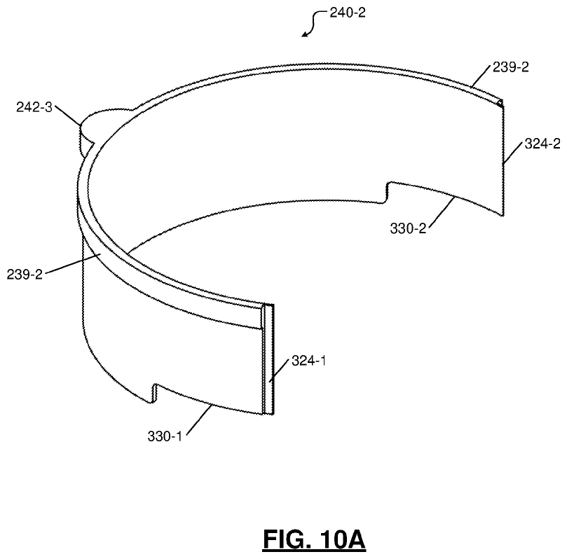

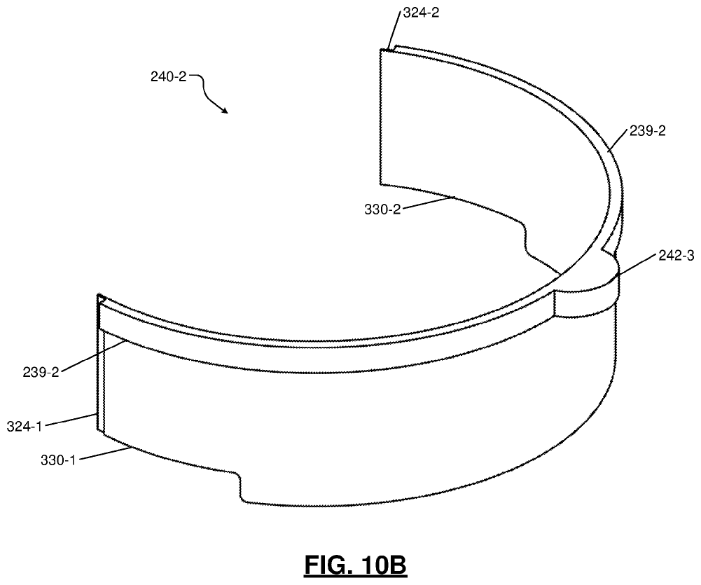

The port liner 272 comprises a second portion 276 that extends perpendicularly from a second end 282 of the first portion 274 along the ID of the sidewall 224 of the well 130. The second portion 276 also extends laterally from the second end 282 of the first portion 274 along the ID of the sidewall 224 of the well 130. An upper end 275 of the second portion 276, the second end 282 of the first portion 274, an upper surface 277 of the first portion 274, and the ID of the sidewall 224 of the well 130 form a slot 278 (shown in FIG. 5A). Bottom portions of the wall liners 240 comprise cutouts (see FIGS. 10A and 10B) that fit into the slot 278 as explained below in further detail with reference to FIGS. 9A-11.

### Bottom Liners

FIG. 6 shows the annular bottom liner 220. The ID and OD of the annular bottom liner 220 are already described above with refer to FIG. 3A. The bottom liner 220 comprises a recess 284 that extends radially outwards from the OD of the bottom liner 220. The bottom of the wall liners 240 rests on the recess 284. The thickness of the wall liners 240 (i.e., a distance between the ID and OD of the wall liners 240) matches a width of the recess 284.

Additionally, the bottom liner 220 comprises two notches 286 and 288. When the bottom liner 220 is arranged on the upper surface 222 of the bottom of the well 130, the notches 286 and 288 align with lower ends 279 of the second portions 276 of the port liners 272 (see FIGS. 5A and 5B). The lower ends 279 of the second portions 276 of the port liners 272 fit into the notches 286 and 288.

FIGS. 7A and 7B show the disc-shaped bottom liner 260 in further detail. FIG. 7A shows a top view of the bottom liner 260. FIG. 7B shows a bottom view of the bottom liner 260. The ID and OD of the annular bottom liner 260 are already described above with refer to FIG. 4A. In FIGS. 7A and 7B, the bottom liner 260 is shown to comprise features that can be used with the volume reducer 230. If the volume reducer 230 is not used with the bottom liner 260, the features of the bottom liner 220 that relate to the volume reducer 230 can be omitted.

In FIG. 7A, the bottom liner 260 comprises a recess 300 that extends radially outwards from the OD of the bottom liner 260. The bottom of the wall liners 240 rests on the recess 300. The thickness of the wall liners 240 (i.e., a distance between the ID and OD of the wall liners 240) matches a width of the recess 300.

The upper surface of the bottom liner 260 comprises a plurality of locator pins 302-1, 302-2, 302-3, and 302-4 (collectively the locator pins 302) for aligning the wall liners 240 between the locator pins 302 and the ID of the sidewall 224 of the well 130 and fitting the wall liners 240 into the recess 300.

The upper surface of the bottom liner 260 comprises a plurality of locator pins 304-1, 304-2, and 304-3 (collectively the locator pins 304) for aligning the outer sidewall 234 of the volume reducer 230 with the upper surface 222 of the bottom of the well 130.

The upper surface of the bottom liner 260 comprises a plurality of notches or orientation tabs 306-1, 306-2, and 306-3 (collectively the orientation tabs 306) to align and orient the volume reducer 230 on the upper surface of the bottom liner 260. As shown and described below with reference to FIGS. 12A-13, the volume reducer 230 comprises corresponding protrusions that fit into the orientation tabs 306. Due to the orientation tabs 306, the plurality of stepped (recessed) portions 232 of the volume reducer 230 are oriented correctly to receive the base portions 178 of the lift pin assemblies 174 that rest on the recessed portions 232. Circular markings 308-1, 308-2, 308-3 (collectively the circular markings 308) on the upper surface of the bottom liner 260 indicate where the base portions 178 of the lift pin assemblies 174. If the volume reducer 230 is installed directly on the upper surface 222 of the bottom of the well 130, similar locator pins, orientation tabs, and markings can be provided on the upper surface 222 of the bottom of the well 130.

Additionally, the bottom liner 260 comprises two notches 310 and 312. When the bottom liner 260 is arranged on the upper surface 222 of the bottom of the well 130, the notches 310 and 312 align with lower ends 279 of the second portions 276 of the port liners 272. The lower ends 279 of the second portions 276 of the port liners 272 fit into the notches 286 and 288.

The bottom liner 260 further comprises an opening 314 at the center of the bottom liner 260 that defines the ID of the bottom liner 260. The stem portion 162 of the pedestal 150 passes through the opening 314. The opening 314 aligns with the opening 290 on the upper surface 222 of the bottom of the well 130. The stem portion 162 of the pedestal 150 passes through the opening 314 into the opening 290 on the upper surface 222 of the bottom of the well 130.

In FIG. 7B, a bottom surface of the bottom liner 260 comprises a plurality of locator pins 316-1, 316-2, and 316-3 (collectively the locator pins 316) for aligning the bottom liner 260 with the upper surface 222 of the bottom of the well 130. The locator pins 316 fit into the holes 294 on the upper surface 222 of the bottom of the well 130 (see FIG. 5A).

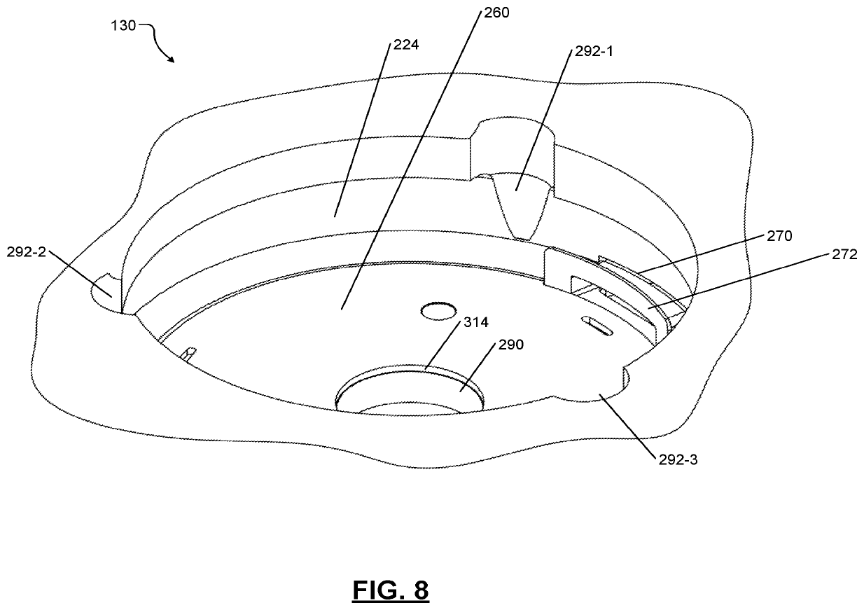

FIG. 8 shows the well 130 with the bottom liner 260 and the port liner 272 and without the volume reducer 230 and the wall liners 240. The bottom liner 260 is fitted to the upper surface 222 of the bottom of the well 130 using the locator pins 316 on the bottom surface of the bottom liner 260 and the corresponding holes 294 on the upper surface 222 of the bottom of the well 130 (all shown and described above with reference to FIGS. 5A-7B). The notches 310 and 312 of the bottom liner 260 are aligned with lower ends 279 of the second portions 276 of the port liners 272 (all shown and described above with reference to FIGS. 5A-7B). The opening 314 at the center of the bottom liner 260 is aligned with the opening 290 on the upper surface 222 of the bottom of the well 130 (all shown and described above with reference to FIGS. 5A-7B).

### Wall Liners

FIGS. 9A-10B show the wall liner 240. As described above with reference to FIG. 3A, the wall liner 240 comprise two semi-circular wall liners that are disposed along the inner sidewall 224 of the well 130. FIGS. 9A and 9B show two perspective views (front and back) of a first semicircular portion 240-1 of the wall liner 240. FIGS. 10A and 10B show two perspective views (front and back) of a second semicircular portion 240-2 of the wall liner 240. The first and second semicircular portions 240-1 and 240-2 are collectively called the wall liner 240 or the wall liners 240.

In FIGS. 9A and 9B, the first semicircular portion 240-1 (hereinafter the first portion 240-1) of the wall liner 240 is shown. The first portion 240-1 comprises the two protrusions 242-1 and 242-2 (one protrusion 242 shown in FIG. 3A) that cover the corresponding access openings 292 on the upper end 226 of the well 130. The protrusions 242-1 and 242-2 are semicircular and match the access openings 292-1 and 292-2, respectively. The protrusions 242-1 and 242-2 extend radially outwards from the upper end of the first portion 240-1.

The ID and OD of the wall liner 240 are already described above with reference to FIG. 3A. The upper end of the first portion 240-1 extends radially outwards along the circumference of the first portion 240-1 to form the flange 239-1. The protrusions 242-1 and 242-2 extend further from the flange 239-1. The first portion 240-1 further comprises recesses 322-1 and 322-2 (collectively the recesses 322) at two ends of the first portion 240-1. The recesses 322 extend along the height of the first portion 240-1 at the two ends of the first portion 240-1. For example, the recesses 322 may be located along the ID of the first portion 240-1.

In FIGS. 10A and 10B, the second semicircular portion 240-2 (hereinafter the second portion 240-2) of the wall liner 240 is shown. The second portion 240-2 comprises the third protrusion 242-3 that covers the corresponding access opening 292 on the upper end 226 of the well 130. The protrusion 242-3 is similar to the protrusions 242-1 and 242-2 (i.e., the protrusion 242-3 is semicircular and matches the third access openings 292-3). The protrusion 242-3 extends radially outwards from the upper end of the second portion 240-2.

The upper end of the second portion 240-2 also extends radially outwards along the circumference of the second portion 240-2 to form a flange 239-2. The flange 239-2 is identical to the flange 239-1. The protrusion 242-3 extends further from the flange 239-2. The protrusions 242-1, 242-2, and 242-3 are collectively called the protrusions 242. The flanges 239-1 and 239-2 are collectively called the flanges 239.

The second portion 240-2 further comprises recesses 324-1 and 324-2 (collectively the recesses 324) at two ends of the second portion 240-2. The recesses 324 extend along the height of the second portion 240-2 at the two ends of the second portion 240-2. For example, the recesses 324 may be located along the OD of the second portion 240-2.

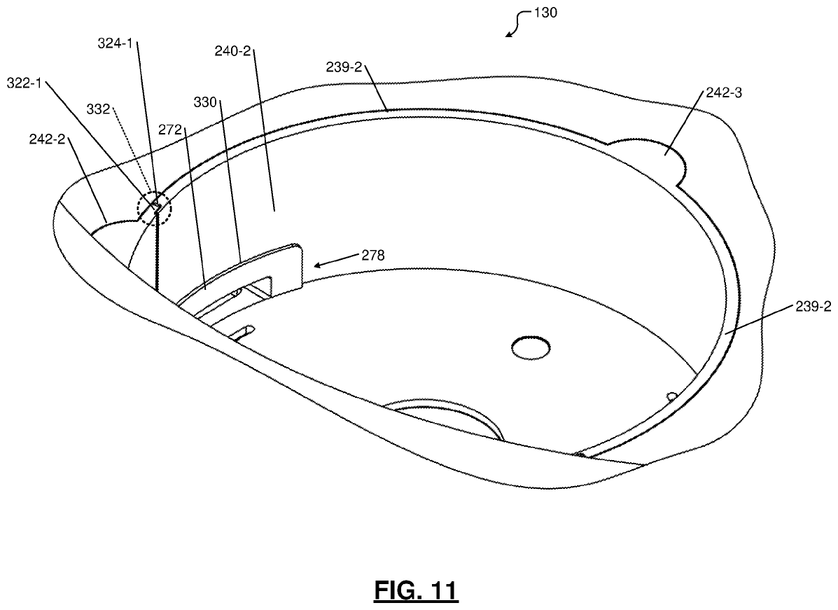

Due to the recesses 322 and 324 located along the ID and OD of the first and second portions 240-1 and 240-2, The first and second portions 240-1 and 240-2 mate with each other to form the cylindrical wall liner 240. Specifically, the recesses 322 and 324 mate with each other, and the flanges 239-1 and 239-2 mate with each other (see FIG. 11). The second portion 240-2 further comprises two cutouts 330-1, 330-2 (collectively the cutouts 330) along a lower end of the second portion 240-2 at the two ends of the second portion 240-2. As shown in FIG. 11, the cutouts 330 fit into the slot 278 in the port liner 272 (shown in FIG. 5A).

FIG. 11 shows the well 130 with the bottom liner 260, the port liner 272, and the wall liners 240 and without the volume reducer 230. The bottom liner 260 is fitted to the upper surface 222 of the bottom of the well 130 as described above with reference to FIG. 8. Additionally, the wall liners 240 are installed in the well 130 along the inner sidewall 224 of the well as described with reference to FIGS. 3A and 9A-10B. The first and second portions 240-1 and 240-2 mate at 332. The cutouts 330 fit into the slot 278 in the port liner 272 and are therefore not visible.

### Volume Reducer

FIGS. 12A and 12B show the volume reducer 230 in further detail. FIG. 12A shows a top perspective view of the volume reducer 230. FIG. 12B shows a bottom perspective view of the volume reducer 230. As already described with reference to FIG. 3A, the volume reducer 230 is generally cylindrical and comprises stepped (recessed) portions 232 that extend radially inwards from the OD of the outer sidewall 234 of the volume reducer 230. The base portions 178 of the lift pin assemblies 174 rest on the recessed portions 232 (e.g., at locations such as a location shown at 237). Other features such as the OD, ID, and height of the volume reducer 230 are already described above with reference to FIG. 3A. The description is not repeated for brevity.

The volume reducer 230 also comprises an opening 334 defined by the inner sidewall 236 of the volume reducer 230. The opening 334 aligns with the opening 314 at the center of the bottom liner 260 and the opening 290 at the center of the upper surface 222 of the bottom of the well 130. The stem portion 162 of the pedestal 150 passes through the openings 334 and 314 into the opening 290 at the center of the upper surface 222 of the bottom of the well 130.

In FIG. 12B, the inner sidewall 236 and the stepped (recessed) portions 232 are visible more clearly. As can be seen, the inner sidewall 236 is cylindrical and concentric with the outer sidewall 234. As already described with reference to FIG. 3A, the height of the inner sidewall 236 is less than the height of the outer sidewall 234. The bottom of the volume reducer is open (i.e., not enclosed). A plurality of protrusions 336-1, 336-2, and 336-3 (collectively the protrusions 336) are arranged at the bottom end (rim) of the outer sidewall 234. The protrusions 336 fit into the orientation tabs 306 on the bottom liner 260 a shown and described with reference to FIGS. 7A and 7B. If the bottom liner 220 is used instead of the bottom liner 260, the protrusions 336 fit into similar the orientation tabs 306 provided on the upper surface 222 of the bottom of the well 130.

Note that the shape of the volume reducer 230 can be varied. For example, the outer sidewall 234 can taper radially inwards towards the inner sidewall 236 from the bottom of the outer sidewall 234 towards the upper surface 238 of the volume reducer 230. Further, while the bottom of the volume reducer 230 is shown and described as being open (i.e., not closed), in some examples, the bottom of the volume reducer 230 may be closed using a disc-shaped plate similar to the bottom liner 260 and having a diameter of the outer sidewall 234 to form an enclosed volume reducer. Many other variations in the shape of the volume reducer 230 are possible so long as the volume reducer 230 reduces the volume of the well 130, comprises locations at which to rest the base portions 178 of the lift pin assemblies 174, and allows gas flow around the volume reducer similar to that described with reference to FIG. 3B.

FIG. 13 shows the well 130 with the bottom liner 220 or 260, the port liners 272, the wall liners 240, and the volume reducer 230. The port liners 272 (not visible) are installed in the exhaust ports 270 as shown and described above with reference to FIGS. 5A and 5B. The bottom liner 220 or 260 (not visible) is fitted to the upper surface 222 of the bottom of the well 130 as shown and described above with reference to FIGS. 3A and 4A and FIGS. 6-8. The wall liners 240 are installed in the well 130 along the inner sidewall 224 of the well 130 as shown and described above with reference to FIGS. 3A and 9A-11. All three protrusions 242-1, 242-2, and 242-3 of the wall liners 240 that fit into the corresponding access openings 292 are shown. Further, both mating points 232 of the first and second portions 240-1 and 240-2 of the wall liners 240 are also shown. The volume reducer 230 is installed in the well 130 as shown and described above with reference to FIG. 3A and FIGS. 12A-13.

### Shroud

FIG. 14 shows a perspective view of the shroud 200. The OD, ID, and height of the shroud 200 are already described above with reference to FIG. 3A. The description is not repeated for brevity. A plurality of the mounting locations 217 comprising the holes 216 (both shown in FIG. 3A) are shown. The holes 216 are drilled in respective mounting locations 217. The mounting locations 217 protrude radially inwardly from the ID of the shroud 200. Note that the number of mounting locations 217 and the holes 216 can be different (fewer or more) than those shown. Further, the spacing between the mounting locations 217 can be different than that shown.

The bottom liners 220 and 260, the wall liners 240, the volume reducer 230 can be made of a metallic material such as aluminum or an alloy. The bottom liners 220 and 260, the wall liners 240, the volume reducer 230 can comprise a coating of an anticorrosive material such as electroless nickel plating. The shroud 200 and the pins 210 can be made of a ceramic material such as aluminum nitride. The lift pins 176 can be made of a ceramic material such as sapphire.

Note that using all of the shroud 200, the wall liner 240, the volume reducer 230, the bottom liner 220 or 260, and the port liner 270 reduces contamination and crosstalk as described above. However, in some processes, depending on levels of contamination and crosstalk that may be acceptable, the shroud 200 and one or more of the wall liner 240, the volume reducer 230, the bottom liner 220 or 260, and the port liner 270 may be used in different combinations. For example, in some processes, depending on levels of contamination and crosstalk that may be acceptable, one or more of the wall liner 240, the volume reducer 230, the bottom liner 220 or 260, and the port liner 270 may be omitted.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

What is claimed is:

1. A station of a substrate processing system comprising:
a pedestal arranged in a well of the station, the pedestal comprising a base portion to support a substrate and a stem portion extending from the base portion into the well of the station; and
a shroud coupled to the base portion of the pedestal, the shroud surrounding the base portion and extending along the stem portion into the well of the station.

2. The station of claim 1 further comprising a liner lining an inner sidewall of the well of the station.

3. The station of claim 1 further comprising a liner lining a pedestal-facing surface of a bottom of the well of the station.

4. The station of claim 1 further comprising a hollow object disposed in the well of the station, the hollow object being of smaller dimensions than the well of the station.

5. The station of claim 1 further comprising:
a first liner lining an inner sidewall of the well of the station;
a second liner lining a pedestal-facing surface of a bottom of the well; and
a hollow object disposed in the well, the well and the first liner being greater in height than the hollow object.

6. The station of claim 5 wherein the well comprises an exhaust port, the station further comprising a third liner lining the exhaust port wherein the first and second liners mate with the third liner.

7. The station of claim 5 wherein the second liner is annular with an outer edge contacting the first liner and an inner edge contacting the hollow object.

8. The station of claim 5 wherein a gap is maintained between the first liner and the shroud.

9. The station of claim 5 wherein the shroud, the first and second liners, the hollow object, the well, and the pedestal are concentric.

10. The station of claim 5 wherein the hollow object comprises an outer sidewall of a smaller diameter than the first liner and an inner sidewall of a diameter greater than the stem portion of the pedestal and wherein the first liner is taller than the hollow object.

11. The station of claim 10 wherein the second liner and the well comprise openings at respective centers and wherein the stem portion of the pedestal passes through the inner sidewall of the hollow object and through the openings of the second liner and the well.

12. The station of claim 10 wherein the well comprises:
an exhaust port; and
an inlet for a gas,
wherein the gas flows around the hollow object and exits the well through the exhaust port.

13. The station of claim 12 further comprising a third liner that lines the exhaust port and mates with the first and second liners.

14. The station of claim 1 further comprising an edge ring disposed around the base portion of the pedestal wherein the shroud is mounted to the edge ring with a gap maintained between the shroud and the edge ring.

15. The station of claim 14 wherein the well comprises:
a first liner lining an inner sidewall of the well;
a second liner lining a pedestal-facing surface of a bottom of the well;
a hollow object disposed in the well, the well and the first liner being greater in height than the hollow object;
an exhaust port; and
an inlet,
wherein gases enter the well through the gap and the inlet, flow around the hollow object, and exit the well through the exhaust port.

16. The station of claim 15 further comprising a third liner that lines the exhaust port and mates with the first and second liners.

17. The station of claim 1 wherein the well comprises an exhaust port, the station further comprising:
a first liner lining an inner sidewall of the well;
a second liner lining a pedestal-facing surface of a bottom of the well; and
a third liner lining the exhaust port and mating with the first and the second liners.

18. The station of claim 17 further comprising a hollow object disposed in the well, the hollow object being of smaller dimensions than the well, wherein:
the first liner is greater in height than the hollow object; and
the second liner is annular with an outer edge contacting the first liner and an inner edge contacting the hollow object.

19. The station of claim 18 further comprising an edge ring disposed around the base portion of the pedestal wherein:
the shroud is mounted to the edge ring with a gap maintained between the shroud and the edge ring;
the well comprises an inlet; and
gases enter the well through the gap and the inlet, flow around the hollow object, and exit the well through the exhaust port.

20. The station of claim 1 further comprising:
an object comprising an outer sidewall, an inner sidewall, and a first surface connecting first ends of the outer sidewall and the inner sidewall;
wherein the object rests on a second surface of a bottom of the well, the second surface being opposite the first surface; and
wherein a height of the object is less than a depth of the well of the station.

21. The station of claim 20 further comprising:
a first liner lining an inner sidewall of the well; and
a second liner lining the second surface of the bottom of the well;
wherein the first liner is taller than the object; and
wherein the second liner is annular with an outer edge contacting the first liner and an inner edge contacting the outer sidewall of the object.

22. The station of claim 20 wherein the inner sidewall of the object is shorter than the outer sidewall of the object and does not contact the second surface of the bottom of the well.

23. The station of claim 20 further comprising a plurality of lift pin assemblies to support the substrate wherein the object comprises recessed portions on which the lift pin assemblies rest.

24. The station of claim 23 wherein the well comprises a plurality of openings along a pedestal-facing rim of the well to access the lift pin assemblies and wherein the first liner comprises protrusions extending radially outwardly and covering the openings.

25. The station of claim 20 further comprising a heat shield coupled to a well-facing end of the base portion wherein the shroud surrounds the heat shield.

26. The station of claim 1 wherein the well comprises an exhaust port, the station further comprising:
a first liner lining the exhaust port; and
a second liner lining an inner sidewall of the well and mating with the first liner.

27. The station of claim 26 further comprising a third liner lining a pedestal-facing surface of a bottom of the well and mating with the first and second liners.

28. The station of claim 27 further comprising a hollow object disposed in the well wherein the well and the second liner are greater in height than the hollow object.

29. The station of claim 28 wherein the third liner is annular with an outer edge contacting the second liner and an inner edge contacting the hollow object.

30. The station of claim 28 further comprising an edge ring disposed around the base portion of the pedestal wherein:
the shroud is mounted to the edge ring with a gap maintained between the shroud and the edge ring;
the well comprises an inlet; and
gases enter the well through the gap and the inlet, flow around the hollow object, and exit the well through the exhaust port.
